(19) United States
(12) Patent Application Publication
(10) Pub. No.: US 2011/0260709 A1
(43) Pub. Date: Oct. 27, 2011

(54) Energy Monitoring Device

(76) Inventors: Kevin M. Johnson, Natick, MA (US); John D. Gundlach, Acton, MA (US)

(21) Appl. No.: 13/124,830

(22) PCT Filed: Oct. 19, 2009
(86) PCT No.: PCT/US2009/061181

§ 371 Date: Jul. 11, 2011

Related U.S. Application Data
(60) Provisional application No. 61/106,210, filed on Oct. 17, 2008.

(51) Int. Cl. G01R 19/00; G01R 31/00

(52) U.S. Cl. 324/96; 324/76.11

(57) ABSTRACT

A device, system and method for monitoring a switchable load operably coupled to a positionable switch. The device including a face plate mountable on the positionable switch, a sensor mounted on the face plate, wherein the sensor is configured to detect the position of the positionable switch and electronics mounted on the face plate and operably coupled to the sensor, wherein the electronics are configured to determine the amount of time the positionable switch has been in a given position.

### FIELD OF INVENTION

The present disclosure relates to a device for monitoring energy usage of a switchable load, such as wired through a light switch.

### BACKGROUND

Energy costs are on the rise and lighting may be considered a relatively large portion of the total energy consumption for a residence or business. Trying to monitor the cost associated with lighting can prove difficult however. Many lights may be hardwired into the infrastructure of a residence or building so their on-time and total energy consumption may be hard to break out from the rest of the system. Electronic loads, which may include lighting, that plug into standard wall outlets may be monitored by a number of different products on the market such as the KILL-A-WATT available from P3 International. However, for hardwired lighting provided on switched circuits and other loads that may be on switched circuits there may not be a relatively easy way to determine power consumption. One possible way to address this problem may be to create a device at the switch that may be able to log the “on-time” of a switch and display use-time, power consumption and costs associated with the light switch. The user may then make informed decisions about the use of load on the light switch and how it may impact their energy consumption.

### SUMMARY

According to one aspect, the present disclosure relates to a device for monitoring a switchable load operably coupled to a positionable switch. The device may include a face plate mountable on the positionable switch, a sensor mounted on the face plate, wherein the sensor is configured to detect the position of the positionable switch, and electronics mounted on the face plate and operably coupled to the sensor, wherein the electronics are configured to determine the amount of time the positionable switch has been in a given position.

Another aspect of the present disclosure relates to a system for monitoring the state of two or more positionable switches. The system may include at least two face plates, each face plate including a sensor for detecting the position of the positionable switch, mounted on each of the face plates, electronics mounted on the face plates and operably coupled to the sensor, a transmitter operably coupled to the electronics, and a receiver operably coupled to the electronics. At least one of the at least two face plates may be configured to communicate the position of the positionable switch to another of the at least two face plates.

A further aspect of the present disclosure relates to a method for monitoring a switchable load connected to a positionable switch. The method may include detecting the position of the positionable switch at a time frequency and estimating the amount of time the positionable switch has been in a given position.

### BRIEF DESCRIPTION OF THE DRAWINGS

The above-mentioned and other features of this disclosure, and the manner of attaining them, may become more apparent and better understood by reference to the following description of embodiments described herein taken in conjunction with the accompanying drawings, wherein:

FIG. 1a illustrates an example of an energy monitoring device;

FIG. 1b illustrates the back of the energy monitoring device of FIG. 1a; and

FIG. 2 illustrates an example of circuitry in an energy monitor device.

### DETAILED DESCRIPTION

The present disclosure relates to an energy monitor device, which may take the form of a face plate. The device may include embedded electronics that monitors the state of a switch and displays information about the energy consumed by the load the switch controls. A switch may include a toggle switch (such as a light switch), which may be activated by a mechanical lever, handle or rocking mechanism. A switch may also include a dimmer switch, a rotary switch (such as a fan controller), a keyed switch (activated by the positioning of a key into a slot and/or rotating of the key), a push button, or any other actuator that may close or open an electrical circuit, directly or indirectly by adjustment of position.

The energy monitor device may include a sensor to determine the position of a given switch (on or off) or control input. When the switch is turned to the “on” position, the energy monitor device may automatically start counting “on-time” just like a stopwatch and as the switch is cycled on and off over time, the on-time may be logged. Using information regarding on-time of the switch in conjunction with data entered by the user, or transmitted to the device regarding the power consumed by the load controlled by the switch, the energy monitoring device may then display estimated power consumption such as watt hours or kilowatt hours. Power consumption may be calculated using different user defined increments of time such as the last 24 hrs, the last 30 days, the last year, or since the last reset.

Installing such a device may be no different than installing a standard face plate over a wall switch or outlet. For example, the energy monitoring device may substitute for a standard face plate. Similar to a standard face plate, the energy monitoring face plate may define an opening to receive the switch or outlet receptacles providing access to the switch or outlet receptacles. Furthermore, the energy monitoring face plate may be affixed to the switch or outlet with screws.

In one embodiment, the device may not make any electrical contact with the switch itself, providing a relatively safe and easy installation of the energy monitor device. It may be appreciated that the device may be battery or solar powered. Additionally, because the energy monitoring device is not electrically contacting the switch itself, the energy monitoring device may be relatively easy to move to other light switches within the residence should the user decide to monitor other locations or circuits. Other configurations may include multi-switch face plates that may monitor switches independently and also sum power consumption from multiple switches.

As may be appreciated, three and four way switches may pose potential problems as the position of a given switch may not correlate to the state of the lights. For example, a three way switch may have two switches controlling a light(s) or other potential load. One solution may include multiple face plates that communicate with each other using, for example, radio frequency (RF) communications, allowing a change in state of the light switches to be known by related face plate devices. Therefore, it may be appreciated that a transmitter and/or a receiver may be positioned in the energy monitoring device configured to receive radio frequency communication from other energy monitoring devices.

In another example, “wasted energy” or energy used when no one is detected as being in a given room may be displayed. The device may incorporate a motion sensor, which may monitor the occupancy of a room. Calculations may then be made of the energy used when no motion was detected, or in other words when the energy may be wasted, and the “wasted energy” may be displayed.

In one embodiment the energy monitoring device may include a sensor for sensing switch position and electronics, including a processor, to process the sensor data. In one example, the sensor may be active or on all the time thereby sensing changes in the state of the switch almost immediately. However, it may be appreciated that if the energy monitoring face plate is running on battery power, this may cause the batteries to discharge at a relatively fast or undesirable rate. Accordingly, in another embodiment it may be desirable to turn the sensor on at a specified time frequency. Using this method the sensor and electronics could be “asleep” or operating at a reduced power load for a large portion of the time thereby extending battery life.

In another embodiment, extending battery life may include analyzing data collected over time and adjusting the frequency (i.e., increasing or decreasing the frequency) the energy monitoring device turns the sensor on based on the data. For many switches changes of state and on time may occur at approximately the same each day. Using data collected over time, the face plate may be configured to pattern usage and tailor its on-time frequency to these patterns. Thus if a switch is turned on at approximately 6 pm each day and off at 10 PM each day the on time frequency may increase around these times while decreasing at all other times, until a new trend may be identified.

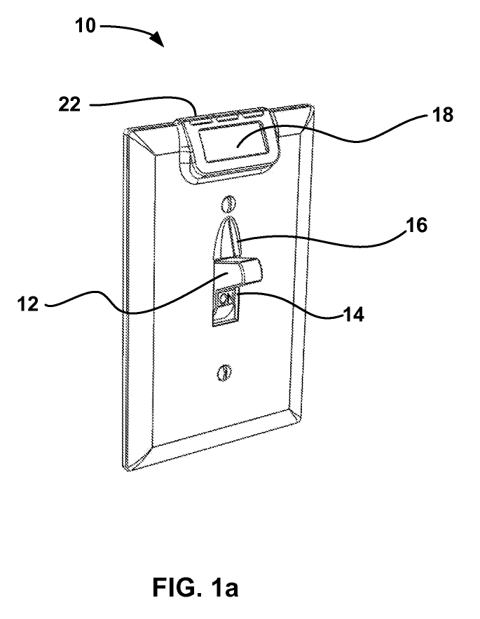

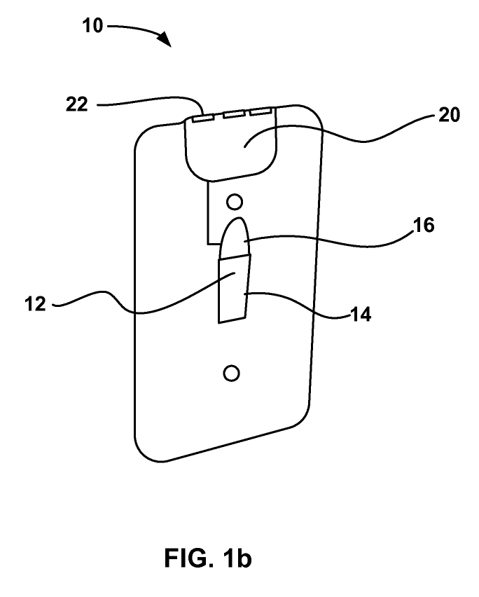

An example of the device is illustrated in FIG. 1a. As noted above, the device 10 may assume the shape of a standard face plate. In the present example, the face plate may accommodate a single switch, however, it may be appreciated that multiple switches or other devices may be provided in the face plate as well. The light switch 12 may be received by a through hole 14 defined in the face plate. The energy monitor device may include a sensor 16 mounted thereon that may detect the position of the switch 12. In addition, a display 18 may be provided which may be in electrical communication with and operably coupled to electronics or circuitry 20 also mounted on or integrated into the device as illustrated in FIG. 1b, a rear view of the device illustrated in FIG. 1a. Furthermore, a series of mode buttons 22 may be provided to control and/or program the device and the display of the device. It may be appreciated that other input devices may be provided in addition to or instead of a mode button, such as a toggle, a receptacle for a USB or other data transfer connector, or a radio frequency receiver as noted above.

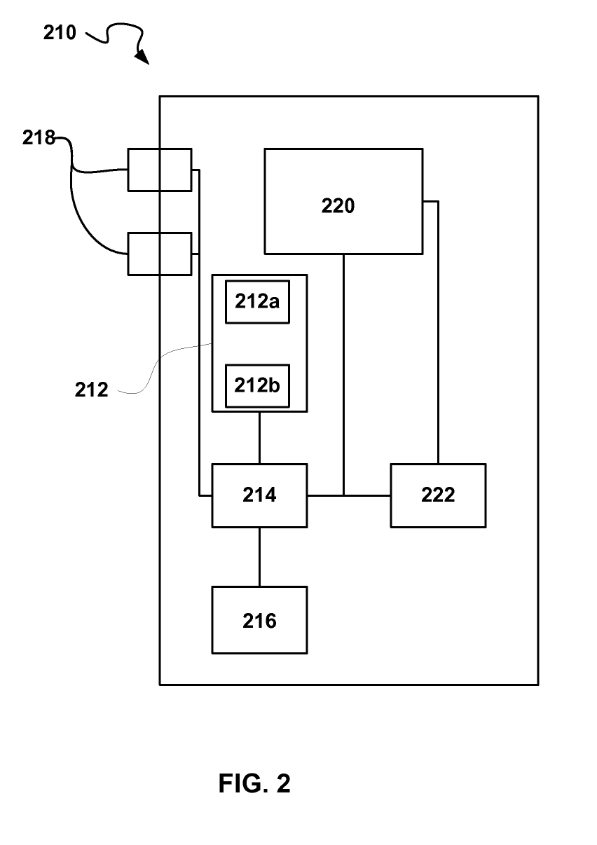

FIG. 2 illustrates an example of circuitry that may be included in the device 210. In one example, the circuitry may include a sensor 212, processor 214, memory 216, inputs 218, display 220 and a power supply 222. In another example, the circuitry may include additional sensors, such as to sense motion or temperature in a room. In a further example, the circuitry may include a receiver, transmitter or a transceiver that may transmit and/or receive information from other energy monitoring devices or a programming/output device, such as a computer. Therefore, it may be appreciated that the transmitter may be configured to send communications regarding the switchable load to other energy monitoring device or may provide such communications to a computer or other device allowing for download of outputs including total power usage and cost information as well as “on” time of the switchable load and/or time periods in which the load was used.

In one embodiment, the position sensor 212 may be an optical sensor, such as an IR sensor. The sensor may include an emitter 212a and a receiver 212b wherein the emitter may emit IR waves or signals (which may have a frequency in the range of 700 nm to 1400 nm, including all values and increments therein.) A portion of the IR waves may be absorbed and/or reflected by a portion of the switch when the switch is in a first given position. The reflected waves may then be sensed by the receiver. However, when in another position, a portion of the IR waves may pass by the switch or fully absorbed by the switch, or may be reflected at a such an angle that relatively few to no waves are detected by the receiver, indicating that the switch may be in a second given position. It may be appreciated that the IR waves may also be reflected at different intensities or at different time periods, depending on the position of the switch.

The receiver 212b may convert the reflected IR waves into an electrical signal and the signal may be received by the processor 214. The processor 214 may then analyze different aspects of the signal, such as the intensity of the signal or the length of time between the sensor emitted the wave versus the length of time the reflected wave was received or whether a signal was received at all to determine the position of the switch.

In another example, the sensor may include a mechanical switch. The mechanical switch may be activated upon moving the switch into a given position sending a signal to the processor 214 that the switch is activated.

The time in which a change in the switch position is sensed may be saved and data including these changes may be accumulated or stored in memory 216 and an estimate may be made as to when the change in position occurred. If the sensor is on continuously, the estimate may be relatively accurate. If the sensor is turned on at a first frequency, it may be appreciated that the estimate may be somewhat inexact. However, in embodiments where adjustments may be made to the frequency in which the sensor is triggered, the sensor may be triggered at a second relatively higher frequency than the first frequency around the time period in which the change in position occurred on, a previous day or the previous two or three days or even a given day the week before. In such a manner, the estimate may be come relatively more accurate.

Further, different outputs may be determined based on the amount of time the switch is in the “on” or “off” position. For example, total power usage and/or total cost may be calculated based on information related to the switch that is provided through the input (such as buttons 22 of FIG. 1a). The information related to the switch may include load size, energy cost, etc. The total power usage or total cost may be calculated over a chosen time period, such as a day, week or month. This information, including the time it is estimated that the switch is on or off may be displayed on the display (see 18 of FIG. 1a). It may be appreciated, that once information related to the switch is received or updated, the device may automatically update the outputs.

As noted above, in another embodiment, the energy monitoring device may use the position sensor or second presence sensor to determine if a person is present in a given area proximal to a load operatively coupled to a switch. The sensor may include a motion sensor or a infrared sensor. Where the presence of a person is not detected, energy used by the load coupled to the switch may be quantified as “wasted” energy or where the presence of a person is detected.

The foregoing description of several methods and embodiments has been presented for purposes of illustration. It is not intended to be exhaustive or to limit the disclosure to the precise configurations and/or forms disclosed, and obviously many modifications and variations are possible in light of the above teaching.

What is claimed is:

1. A device for monitoring a switchable load operably coupled to a positionable switch, comprising:
a face plate mountable on the positionable switch;
a sensor mounted on said face plate, wherein said sensor is configured to detect the position of the positionable switch;
electronics mounted on said face plate and operably coupled to said sensor, wherein said electronics are configured to determine the amount of time the positionable switch has been in a given position.

2. The device of claim 1, wherein said face plate defines an opening configured to receive the positionable switch.

3. (canceled)

4. (canceled)

5. (canceled)

6. (canceled)

7. (canceled)

8. (canceled)

9. (canceled)

10. (canceled)

11. (canceled)

12. The device of claim 1, wherein at least two sensors are mounted on said face plate.

13. The device of claim 1, further comprising an input operably coupled to said electronics to provide information related to the switchable load.

14. The device of claim 4, wherein said input comprises a receiver, a button, a toggle or combinations thereof.

15. The device of claim 4, wherein said information related to the switchable load includes load size, energy cost, or combinations thereof.

16. The device of claim 1, further comprising a transmitter.

17. The device of claim 1, further comprising a display operably coupled to said electronics.

18. The device of claim 1, wherein said electronics are configured to determine one or more outputs based on said amount of time the positionable switch has been in a given position, wherein said outputs are selected from estimated total power used, amount of time used, time periods of use, cost and combinations thereof.

19. The device of claim 1, wherein said sensor includes an optical sensor.

20. The device of claim 1, wherein said sensor includes a mechanical sensor.

21. A system for monitoring the state of two or more positionable switches comprising:
at least two face plates, each face plate including
a sensor for detecting the position of the positionable switch, mounted on each of said face plates,
electronics mounted on said face plates and operably coupled to the sensor,
a transmitter operably coupled to said electronics, and
a receiver operably coupled to said electronics,
wherein at least one of said at least two face plates are configured to communicate the position of the positionable switch to another of said at least two face plates.

22. The system of claim 21, wherein said at least two or more positionable switches operate a single switchable load.

23. A method for monitoring a switchable load connected to a positionable switch, comprising:
detecting the position of the positionable switch at a time frequency; and
estimating the amount of time the positionable switch has been in a given position.

24. The method of claim 23, further comprising determining one or more outputs from said amount of time the positionable switch has been in a given position, wherein said outputs include estimated total power use, amount of time used, time periods of use, cost or combinations thereof.

25. The method of claim 23, further comprising providing information related to the switchable load, wherein the information related to the positionable switch includes load size, energy cost, or combinations thereof.

26. The method of claim 23, wherein detecting the position of the positionable switch over a time frequency includes emitting one or more signals from a sensor mounted on a face plate at said time frequency.

27. The method of claim 23, further comprising storing data regarding the position of the positionable switch during the course of a given time period and detecting trends regarding a change in position of the positionable switch during the course of the given time period.

28. The method of claim 27, wherein said detecting time frequency is altered from a first time frequency to a second time frequency based on said trends.

29. The method of claim 23, wherein a sensor detects the position of the positionable switch and electronics estimate the amount of time the positionable switch has been in a given position, wherein said sensor is mounted on a face plate mountable on the positionable switch and said electronics are mounted on said face plate and operably coupled to said sensor.

30. The method of claim 29, further comprising providing information related to the switchable load by at least one input operably coupled to said electronics, wherein the information related to the positionable switch includes load size, energy cost, or combinations thereof.

31. The method of claim 30, wherein said input comprises a receiver, a button, a toggle or combinations thereof.

32. The method of claim 29, further comprising determining one or more outputs from said amount of time the positionable switch has been in a given position, wherein said outputs include estimated total power use, amount of time used, time periods of use, cost or combinations thereof, and displaying said outputs on a display operably coupled to said electronics.

33. The method of claim 29, further comprising determining one or more outputs from said amount of time the positionable switch has been in a given position, wherein said outputs include estimated total power use, amount of time used, time periods of use, cost or combinations thereof, and communicating said outputs to another energy monitoring device or a computer via a transmitter operably coupled to said electronics.

34. (canceled)

35. (canceled)

36. (canceled)

37. (canceled)

38. (canceled)

39. (canceled)

40. (canceled)

41. (canceled)

42. (canceled)
